(19) United States
(12) Patent Application Publication
(10) Pub. No.: US 2026/0101734 A1
(43) Pub. Date: Apr. 9, 2026

(54) FULLY SELF-ALIGNED VIA (FSAV) ON SUBTRACTIVE METAL

(71) Applicant: QUALCOMM Incorporated, San Diego, CA (US)

(72) Inventors: Junjing BAO, San Diego, CA (US); John Jianhong ZHU, San Diego, CA (US); Abhishek JAIN, San Diego, CA (US); Giridhar NALLAPATI, San Diego, CA (US)

(21) Appl. No.: 18/908,516

(22) Filed: Oct. 7, 2024

(51) Int. Cl. H01L 21/768; H01L 23/532; H01L 23/535

(52) U.S. Cl. CPC H10W 20/069; H10W 20/20; H10W 20/425

(57) ABSTRACT

An integrated circuit (IC) is described. The IC includes a dielectric layer of a first dielectric material. The IC also includes a first metal layer in the dielectric layer. The first metal layer has a first adhesion layer on a backside surface, a second adhesion layer on a frontside surface of the first metal layer. Additionally, the first metal layer has dielectric alignment structures on the second adhesion layer of a second dielectric material different from the first dielectric material. The IC further includes a second metal layer landing on the second adhesion layer on the frontside surface of the first metal layer, between the dielectric alignment structures.

### BACKGROUND

### Field

Aspects of the present disclosure relate to semiconductor devices and, more particularly, to a fully self-aligned via (FSAV) on a subtractive metal.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

When a zero metal (M0) interconnect layer pitch scales below the twenty (20) nanometer (nm) and beyond a two (2) nm node, a copper (Cu) based metal interconnect resistance significantly increases. This significantly increased resistance is due to an increased volume of a high resistivity barrier (e.g., tantalum nitride (TaN)) layer utilized by the metal interconnect. Potential solutions to the increased interconnect resistance issue include alternative transition metals (e.g., ruthenium (Ru), tungsten (W) and molybdenum (Mo), etc.) as promising candidates for replacing copper as a back-end-of-line (BEOL) interconnect material. Unfortunately, using these alternative transition metals results in high interlayer interconnect capacitance. A fully self-aligned via (FSAV) on a subtractive metal is desired.

### SUMMARY

An integrated circuit (IC) is described. The IC includes a dielectric layer of a first dielectric material. The IC also includes a first metal layer in the dielectric layer. The first metal layer has a first adhesion layer on a backside surface, a second adhesion layer on a frontside surface of the first metal layer. Additionally, the first metal layer has dielectric alignment structures on the second adhesion layer of a second dielectric material different from the first dielectric material. The IC further includes a second metal layer landing on the second adhesion layer on the frontside surface of the first metal layer, between the dielectric alignment structures.

A method for forming a fully self-aligned via is described. The method includes forming a multilayer stack including a first metal layer on a first adhesion layer, a second adhesion layer on the first metal layer, and a hardmask layer on the second adhesion layer. The method also includes performing subtractive metal patterning to form first metal interconnects having the first adhesion layer on a backside surface and the second adhesion layer on a frontside surface. The method further includes forming dielectric alignment structures on the second adhesion layer of the first metal interconnects. The method also includes etching a via opening through a first dielectric layer to expose the second adhesion layer between the dielectric alignment structures of a selected metal interconnect. The method further includes depositing a second metal layer in the via opening and on a surface of the first dielectric layer.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), including a fully self-aligned via (FSAV) on a subtractive metal, in accordance with aspects of the present disclosure.

FIG. 2 is a block diagram illustrating a cross-section of an integrated circuit (IC) device including an interconnect stack of back-end-of-line (BEOL), middle-of-line (MOL) and front-end-of-line (FEOL) layers.

FIG. 3 shows a cross-sectional view illustrating an integrated circuit (IC), having a fully self-aligned via (FSAV) on a subtractive metal, according to aspects of the present disclosure.

FIGS. 4A-4K are block diagrams illustrating formation of the integrated circuit (IC) device of FIG. 3, according to aspects of the present disclosure.

FIG. 5 is a process flow diagram illustrating a method for forming a fully self-aligned via (FSAV) on a subtractive metal, according to aspects of the present disclosure.

FIG. 6 is a block diagram showing an exemplary wireless communications system in which a configuration of the disclosure may be advantageously employed.

FIG. 7 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

These interconnections include back-end-of-line (BEOL) interconnect layers, which may refer to the conductive interconnect layers (e.g., a first BEOL interconnect layer or metal one (M1), metal two (M2), metal three (M3), metal four (M4), etc.) for electrically coupling to front-end-of-line active devices of an integrated circuit. The various BEOL interconnect layers are formed at corresponding back-end-of-line interconnect levels, in which lower BEOL interconnect levels use thinner metal layers relative to upper BEOL interconnect levels. The BEOL interconnect layers may electrically couple to middle-of-line (MOL) interconnect layers, for example, to connect M1 to an oxide diffusion (OD) layer of an integrated circuit. The MOL interconnect layer may include a zero-metal layer (M0) interconnect, and a zero via (V0) for connecting M1 to an active device layer, such as a front-end-of-line (FEOL) layer of an integrated circuit.

When a pitch of the M0 interconnect layer scales below the twenty (20) nanometer (nm) and beyond a two (2) nm node, a copper (Cu) based metal interconnect resistance significantly increases. This significantly increased resistance is due to an increased volume of a high resistivity barrier (e.g., tantalum nitride (TaN)) layer utilized by the metal interconnect. Potential solutions to the increased interconnect resistance issue include alternative transition metals (e.g., ruthenium (Ru), tungsten (W) and molybdenum (Mo), etc.) as promising candidates for replacing copper as a BEOL interconnect material.

According to these potential solutions, the alternative metal is subjected to subtractive etch for achieving a lower resistance as a result of a larger grain size and less grain boundary scattering. For example, one current scheme uses silicon nitride (SiN) as an interlayer dielectric (ILD) because SiN is selective to silicon oxide (SiO₂) to form a fully self-aligned via (FSAV). A FSAV formed using a high K SiN as an ILD, however, suffers from a substantial interlayer interconnect capacitance. In particular, using these alternative transition metals results in high interlayer interconnect capacitance.

Various aspects of the present disclosure provide a fully self-aligned via (FSAV) on a subtractive metal. A process flow for fabrication of an FSAV on a subtractive metal may include front-end-of-line (FEOL) processes, middle-of-line (MOL) processes, and BEOL processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Various aspects of the present disclosure are directed to a fully self-aligned via (FSAV) on a subtractive metal. In some implementations, the FSAV includes a dielectric layer of a first dielectric material as well as a first metal layer in the dielectric layer. In some implementations, the first metal layer includes a hardmask on a surface of the first metal layer and dielectric alignment structures on the hardmask above the first metal layer. In this implementation, the dielectric alignment structures are composed of a second dielectric material different from the first dielectric material. According to various aspects of the present disclosure, a second metal layer lands on the hardmask on the surface of the first metal layer, between a pair of the dielectric alignment structures and above the first metal layer to complete the FSAV.

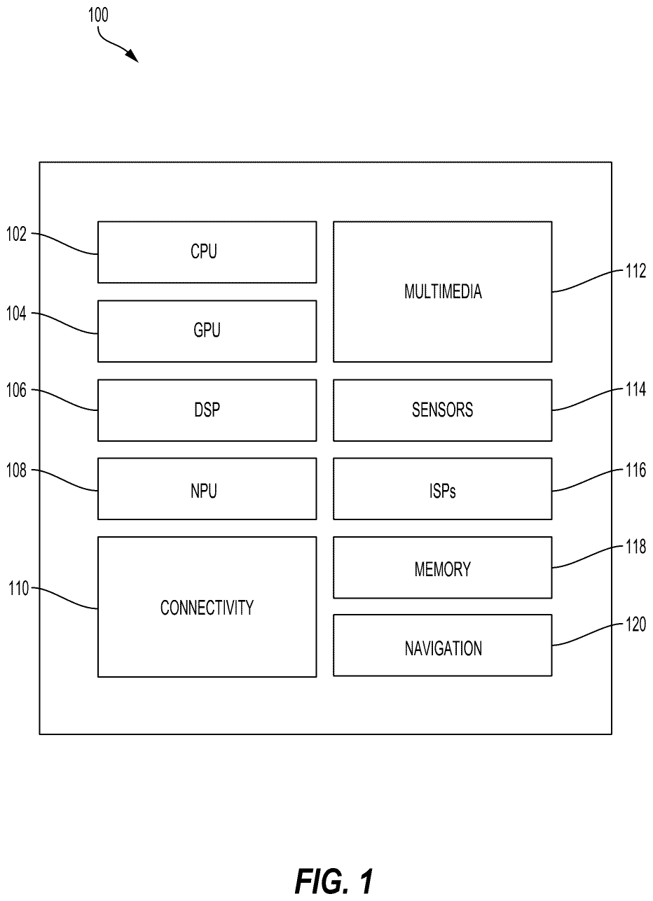

FIG. 1 illustrates an example implementation of a host system-on-chip (SoC) 100, which includes a fully self-aligned via (FSAV) on a subtractive metal, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

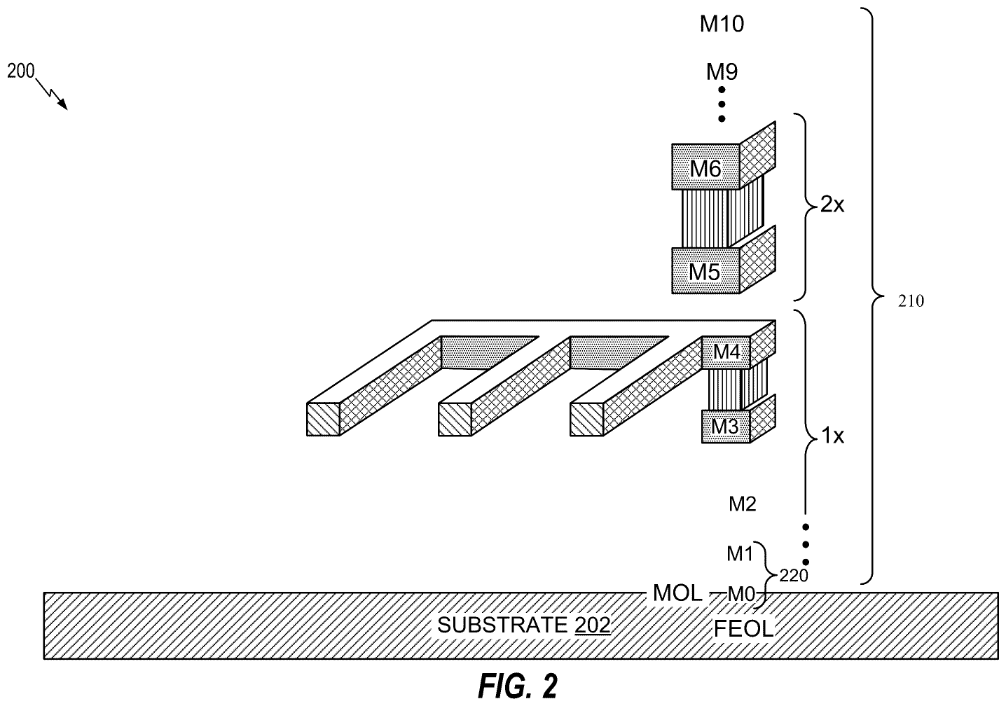

FIG. 2 is a block diagram illustrating a cross-section of an integrated circuit (IC) device 200 including an interconnect stack 210. The interconnect stack 210 of the IC device 200 includes multiple back-end-of-line (BEOL) conductive interconnect layers (M1, . . . , M9, M10) on a semiconductor substrate 202 (e.g., a diced silicon wafer). The semiconductor substrate 202 may be fabricated to include an active device layer (e.g., a front-end-of-line (FEOL) layer) using complementary metal oxide semiconductor (CMOS) technology. Additionally, the interconnect stack 210 includes a middle-of-line (MOL) layer to connect the FEOL layer to a first metal layer (M1) interconnect through a metal zero (M0) layer and a zero via (V0). The various BEOL interconnect layers are formed at corresponding BEOL interconnect levels, in which lower BEOL interconnect levels (e.g., M1) use thinner metal layers relative to upper (e.g., M9) BEOL interconnect levels, and the MOL layer (e.g., M0) uses thinner metal layers relative to the M1 metal layer. In this example, an interconnect structure 220 (e.g., a fully self-aligned via (FSAV)) is formed at an M0 interconnect layer, between M1 and the FEOL.

When a pitch of the M0 interconnect layer scales below the twenty (20) nanometer (nm) and beyond a two (2) nm node, a copper (Cu) based metal interconnect resistance significantly increases. This significantly increased resistance is due to an increased volume of a high resistivity barrier (e.g., tantalum nitride (TaN)) layer utilized by the metal interconnect. Potential solutions to the increased interconnect resistance issue include alternative transition metals (e.g., ruthenium (Ru), tungsten (W) and molybdenum (Mo), etc.) as promising candidates for replacing copper as a back-end-of-line (BEOL) interconnect material.

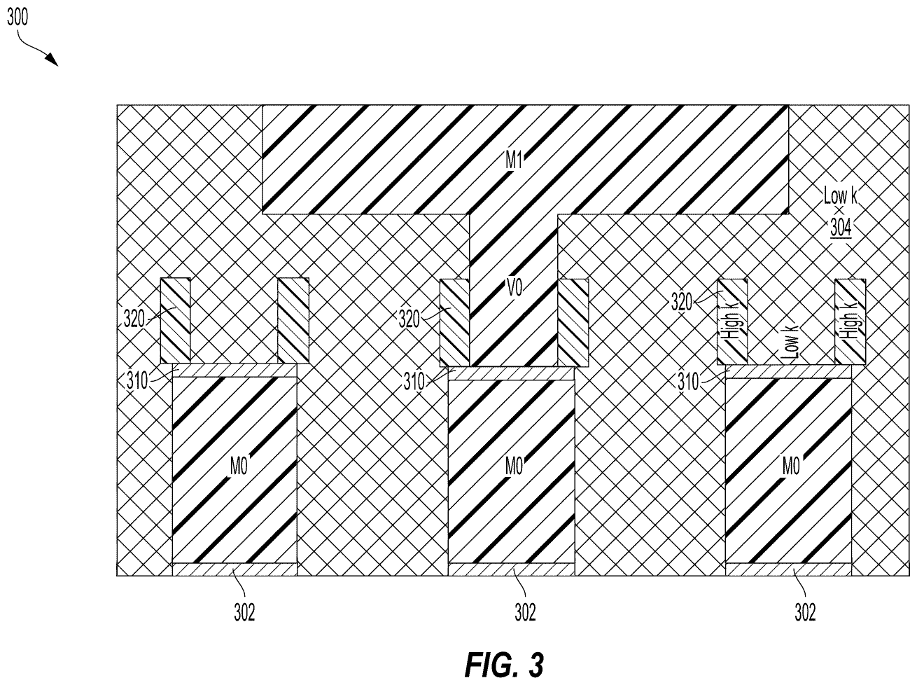

According to these potential solutions, the alternative metal is subjected to subtractive etch for achieving a lower resistance as a result of a larger grain size and less grain boundary scattering. For example, one current scheme uses silicon nitride (SiN) as an interlayer dielectric (ILD) because SiN is selective to silicon oxide (SiO₂) to form a fully self-aligned via (FSAV). An FSAV formed using a high K SiN as an ILD, however, suffers from a substantial interlayer interconnect capacitance. In particular, using these alternative transition metals results in high interlayer interconnect capacitance. Various aspects of the present disclosure are directed to a fully self-aligned via (FSAV) on a subtractive metal, for example, as shown in FIG. 3.

FIG. 3 shows a cross-sectional view illustrating an integrated circuit (IC) 300, having a fully self-aligned via (FSAV) on a subtractive metal, according to aspects of the present disclosure. In some implementations, the IC 300 includes a dielectric layer 304 of a first dielectric material (e.g., a low-K dielectric material) supported by a first adhesion layer 302 (e.g., titanium nitride). Additionally, the IC 300 includes a first metal layer in the dielectric layer 304. In this example, the first metal layer is a middle-of-line (MOL) layer of metal zero (M0) metal interconnects. Although illustrated as an M0 interconnect layer, it should be recognized that the first metal layer may be a back-end-of-line (BEOL) layer.

In some implementations, a pitch of the M0 metal interconnects scales below a twenty (20) nanometer (nm) and beyond a two (2) nm node, replacing a copper (Cu) based metal interconnect with an alternative metal (e.g., ruthenium, tungsten, molybdenum (M0), etc.). As shown in FIG. 3, the M0 metal interconnects include a second adhesion layer 310 (e.g., titanium nitride) on a surface of the M0 metal interconnects. According to various aspects of the present disclosure, dielectric alignment structures 320 are formed on the second adhesion layer 310 above the M0 metal interconnects to enable formation of an FSAV.

According to various aspects of the present disclosure, a second metal layer lands on the second adhesion layer 310 on the surface of an M0 metal interconnect, between the dielectric alignment structures 320 and above the M0 metal interconnect to complete formation of the FSAV. Additionally, the second metal layer is also deposited on a surface of the dielectric layer 304 to form a BEOL, metal one (M1) interconnect (e.g., a second metal layer interconnect). In this example, the FSAV is shown as a zero metal via (V0). Although illustrated as an MOL, V0 via, it should be recognized that the FSAV may be formed in any BEOL layer. Similarly, although illustrated as an M1 metal interconnect, it should be recognized that the second metal layer may be formed in any BEOL layer.

In this implementation, the dielectric alignment structures 320 are composed of a second dielectric material (e.g., a high-K dielectric material) different from the first dielectric material (e.g., a low-K dielectric material) of the dielectric layer 304. According to various aspects of the present disclosure, the IC 300 utilizes a vertical high-K/low-K/high-K (e.g., silicon nitride (SiN)/silicon carbon oxygen hydrogen (SiCOH)/silicon nitride (SiN)) sandwich dielectric structure that is formed above a subtractive metal, such as the M0 metal interconnects. According to various aspects of the present disclosure, the dielectric alignment structures 320 enable formation of a fully self-aligned via.

In some implementations, a high-K dielectric material of the dielectric alignment structures 320 may have a thickness in the range of one (1) to five (5) nanometers (nm) and a height in the range of five (5) to ten (10) nm. Additionally, the low-K dielectric material (e.g., SiCOH, silicon oxygen carbon (SiOC), silicon oxide (SiO₂), etc.) is selectively etched to the high-K dielectric material (e.g., SiN, aluminum nitride (AlN), aluminum oxide (Al₂O₃), etc.) for facilitating formation of a fully self-aligned via that exhibits a lower interlayer interconnect capacitance. In some implementations, a low-K dielectric to high-K dielectric etching selectivity is a predetermined selectivity value that enable formation of the vertical high-K/low-K/high-K sandwich of the dielectric alignment structures 320. For example, for a predetermined selectivity value of ten-to-one (10:1) or greater (e.g., >10:1) an etching rate of the low-k dielectric is greater than ten times (>10×) faster than an etching rate of the high-k dielectric.

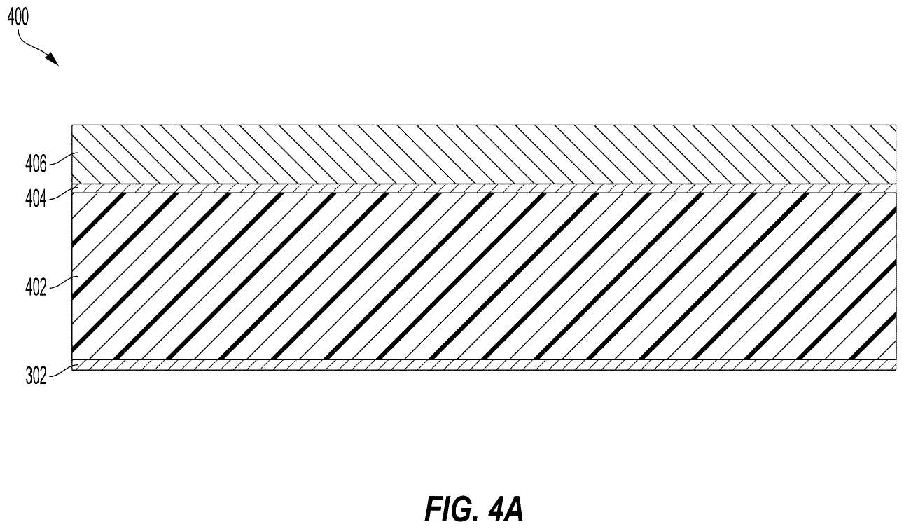

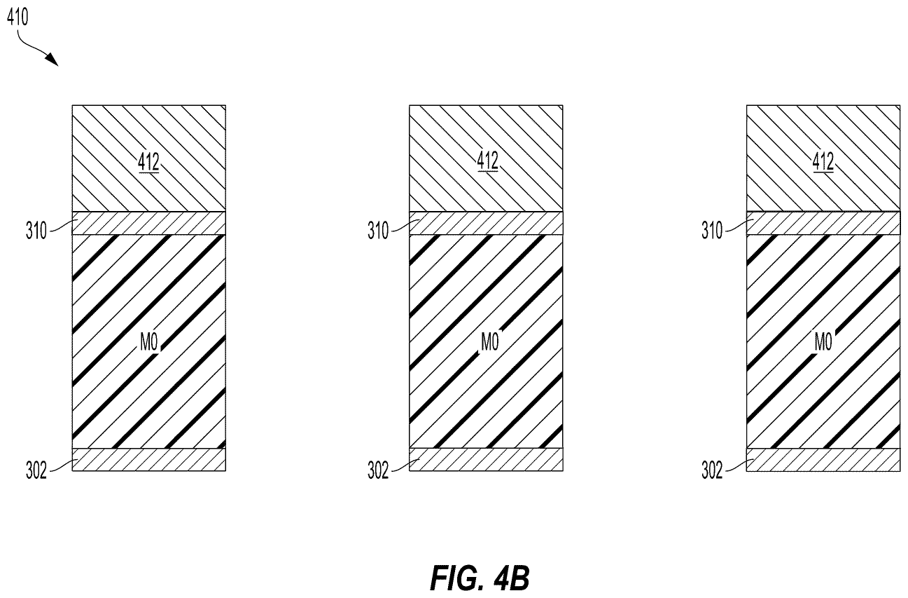

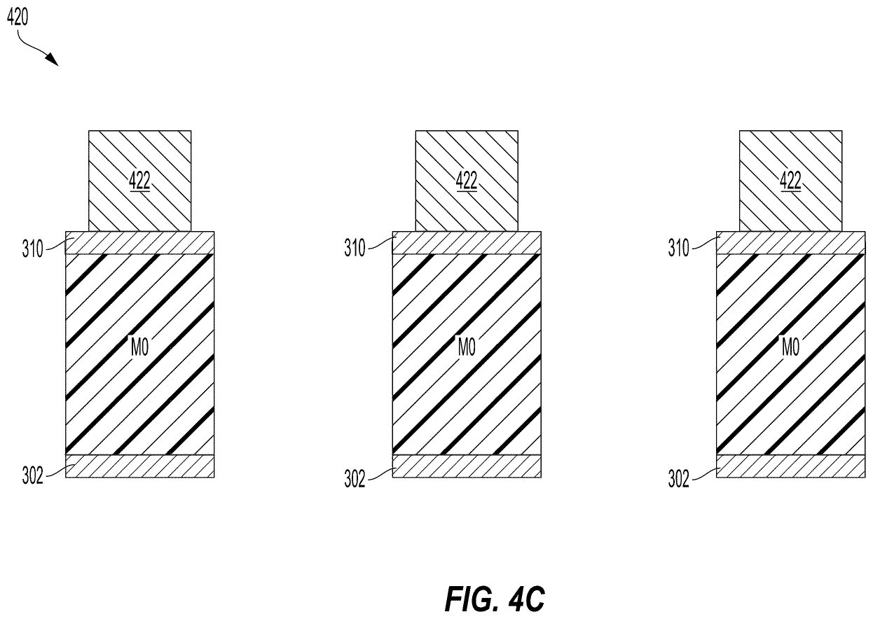

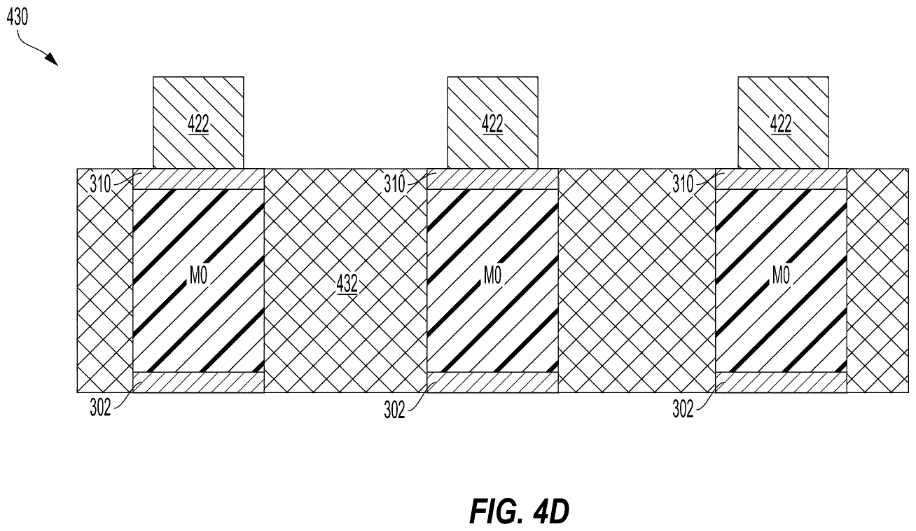

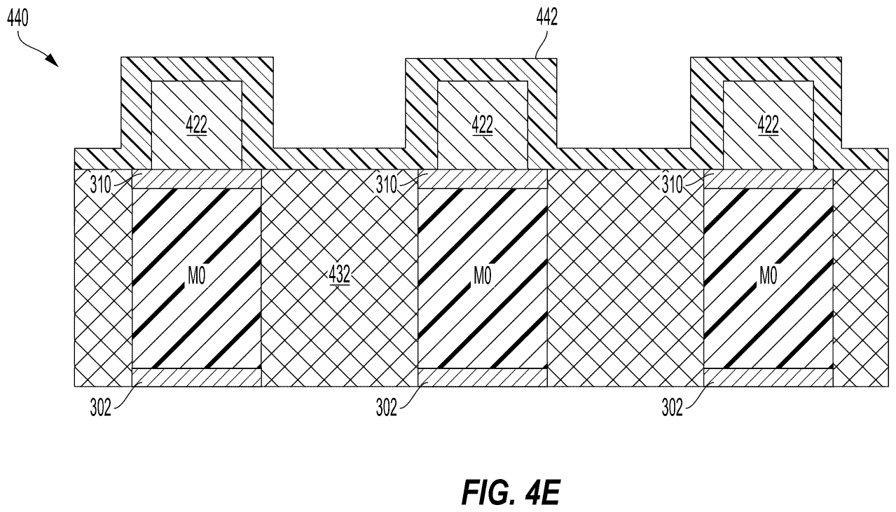

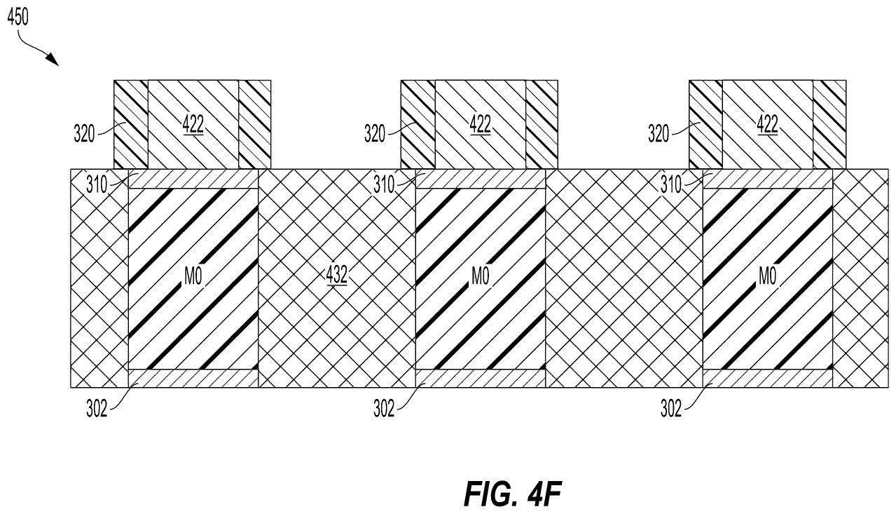

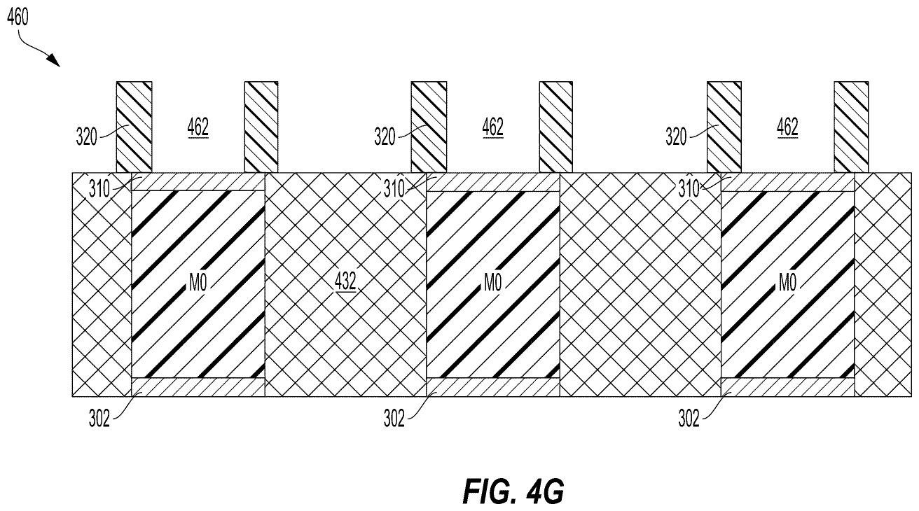

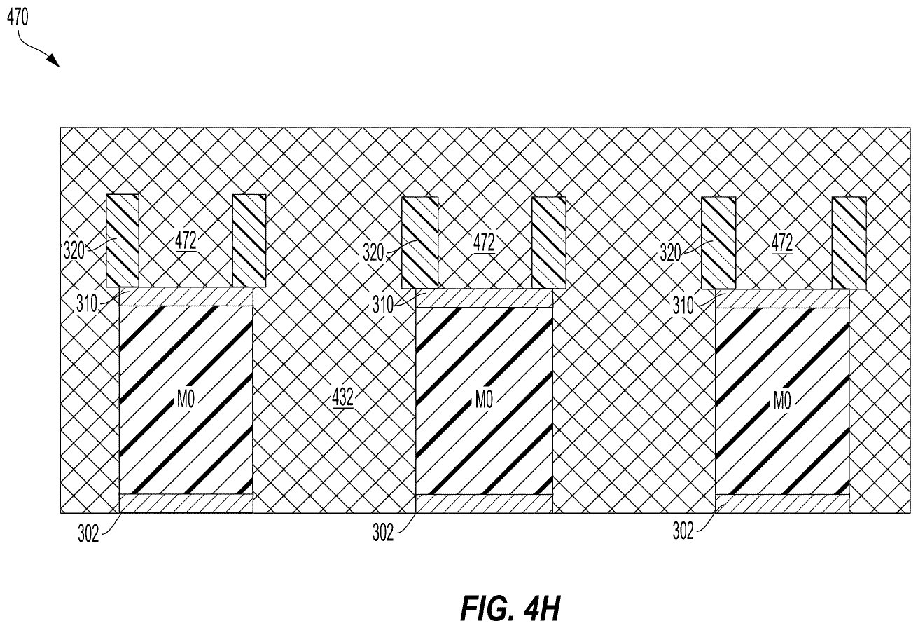

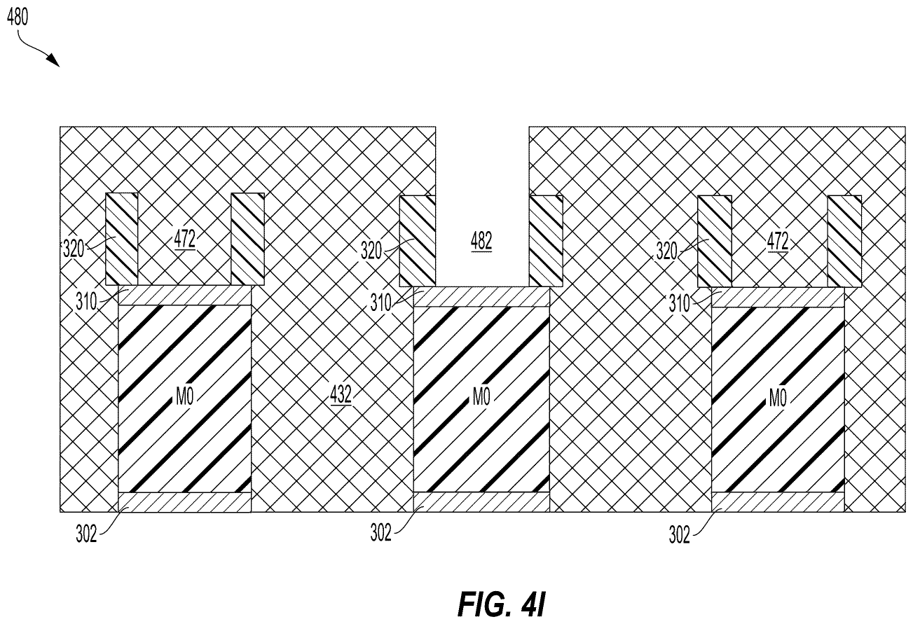

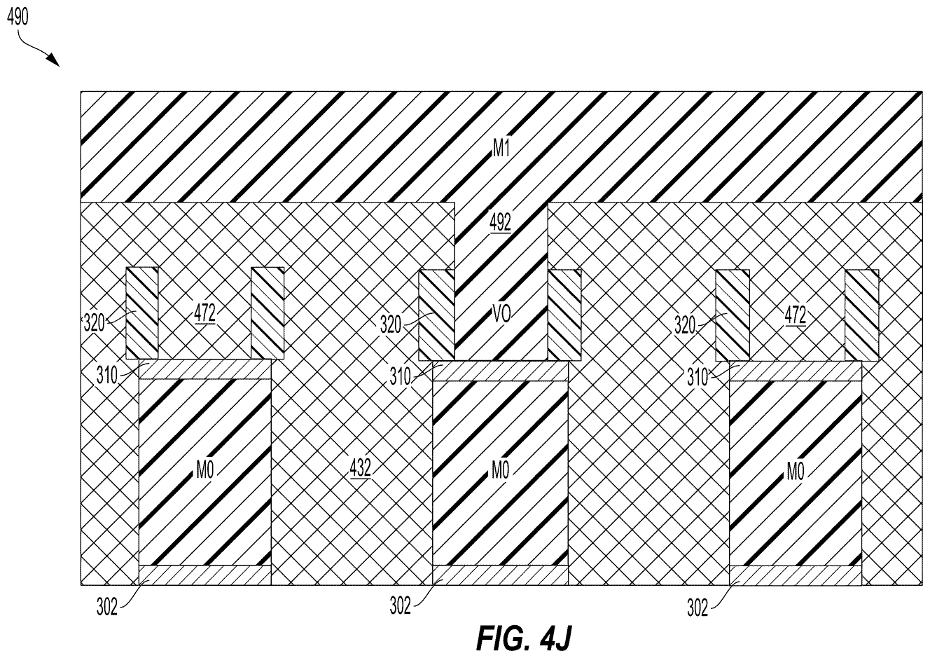

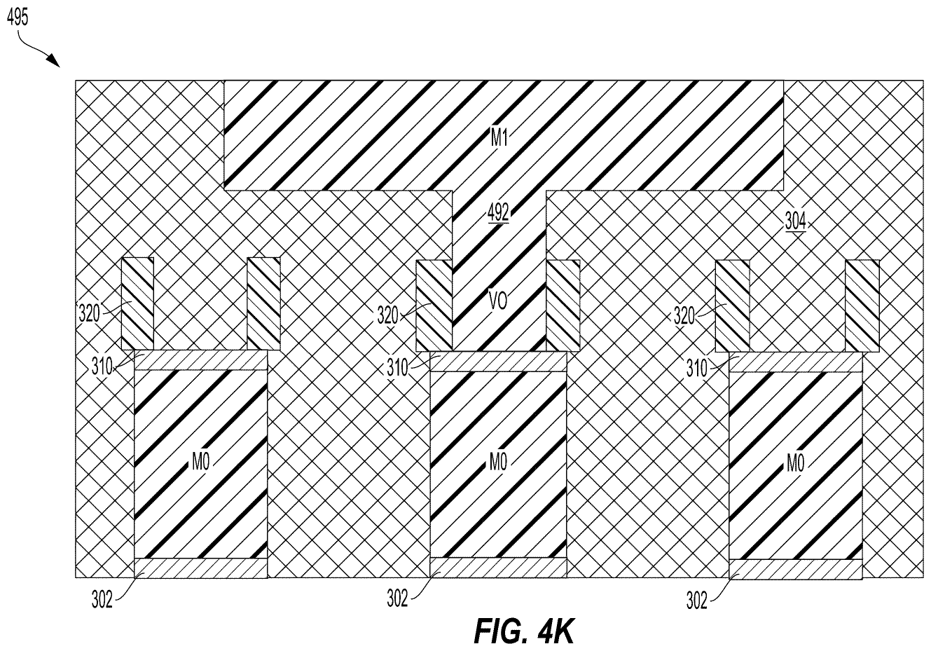

FIGS. 4A-4K are block diagrams illustrating formation of the integrated circuit (IC) 300 of FIG. 3, according to aspects of the present disclosure.

As shown in FIG. 4A, an IC device fabrication process begins at step 400, in which a sequential deposition of the first adhesion layer 302 (e.g., titanium nitride (TiN)), a first alternative metal layer 402 (Ru, W and Mon, etc.), and a first hardmask layer 404 (e.g., SiN) forms a multilayer stack. In this example, the first adhesion layer 302 is formed using an atomic layer deposition (ALD) of an adhesion material (e.g., TiN) having a predetermined thickness (e.g., ˜0.3 nm). Additionally, the first alternative metal layer 402 is formed of a predetermined thickness (e.g., ˜30 nm) using chemical vapor deposition (CVD), physical vapor deposition PVD, ALD, or other like deposition technique. The step 400 is completed by the formation of a second hardmask layer 406 on the first hardmask layer 404. For example, the second hardmask layer 406 is formed by deposition (e.g., CVD) of a hardmask material (e.g., SiO₂) having a predetermined thickness (e.g., ˜10 nm) on the first hardmask layer 404.

As shown in FIG. 4B, at step 410, subtractive metal patterning on the material stack formed in step 400 of FIG. 4A forms the M0 metal interconnects, including the second adhesion layer 310 and portions 412 of the second hardmask layer 406. In this example, portions of a surface of the first adhesion layer 302 are exposed through the subtractive metal patterning performed at step 410.

As shown in FIG. 4C, at step 420, isotropic etching of the portions 412 of the second hardmask layer 406 forms the second hardmasks 422 on the second adhesion layer 310 (e.g., first hardmasks). Additionally, opposing portions of the surface of the second adhesion layer 310 are exposed by performing isotropic etching in step 420.

As shown in FIG. 4D, at step 430, a first dielectric layer 432 (e.g., low-K dielectric material) is deposited on the first adhesion layer 302, sidewalls of the M0 metal interconnects, and sidewalls of the second adhesion layer 310. According to various aspects of the present disclosure, opposing portions of the surface of the second adhesion layer 310 remain exposed following deposition of the first dielectric layer 432, having a thickness equal to the height of the M0 metal interconnects.

As shown in FIG. 4E, at step 440, conformal deposition of a second dielectric layer 442 (e.g., SiN) is performed on the second hardmasks 422, the exposed portions of the second adhesion layer 310, and a surface of the first dielectric layer 432. For example, deposition of the second dielectric layer 442 includes a conformal layer of dielectric material (e.g., SiN) having a predetermined thickness (e.g., 1-5 nm).

As shown in FIG. 4F, at step 450, anisotropic etching of the second dielectric layer 442 exposes a top portion of the second hardmasks 422, and a surface of the first dielectric layer 432 to form the dielectric alignment structures 320 on the second adhesion layer 310. Performing anisotropic etching of the second dielectric layer 442 removes portions of the conformal layer of the second dielectric layer 442 to begin formation of the dielectric alignment structures 320.

As shown in FIG. 4G, at step 460, selective etching of the second hardmasks 422 removes the second hardmasks 422. Removing the second hardmasks 422 exposes a top portion of the second adhesion layer 310 on the M0 metal interconnects through openings 462 between opposing portions of the dielectric alignment structures 320.

As shown in FIG. 4H, at step 470, a third dielectric layer 472 (e.g., a low-K dielectric material) is deposited on the surface of the first dielectric layer 432, the dielectric alignment structures 322, and the exposed portion of the second adhesion layer 310 on the M0 metal interconnects. Additionally, the third dielectric layer 472 fills the openings 462, as shown in FIG. 4G.

As shown in FIG. 4I, at step 480, etching of the third dielectric layer 472 forms a via opening 482 through the third dielectric layer 472 to expose a second adhesion layer 310 between the dielectric alignment structures of a selected M0 metal interconnect. According to various aspects of the present disclosure, forming of the via opening 482 is guided by the dielectric alignment structures 320 to enable formation of a fully self-aligned via (FSAV). In this example, the dielectric alignment structures 320 enable a FSAV zero via (V0) etch.

As shown in FIG. 4J, at step 490, a second alternative metal layer 492 is deposited in the via opening 482 and on an exposed one of the second adhesion layer 310 between dielectric alignment structures 320 of a selected M0 metal interconnect (e.g., a selected metal interconnect). Additionally, the second alternative metal layer 492 is concurrently deposited on a surface of the third dielectric layer 472. In some implementations, the second alternative metal layer 492 (e.g., ruthenium (Ru)) fills the via opening 482 (see FIG. 4I) using a chemical vapor deposition (CVD).

As shown in FIG. 4K, at step 495, a subtractive metal etch of the second alternative metal layer 492. Performing subtractive metal etch at step 495 completes formation of an M1 metal interconnect and the zero-metal layer via V0. Subsequently, a third dielectric layer (e.g., low k SiCOH) is deposited to fill an area previously occupied by the second alternative metal layer 492. Next, a chemical mechanical polishing (CMP) planarization of the dielectric layer 304 and the M1 metal interconnect completes formation of the IC 300, as shown in FIG. 3.

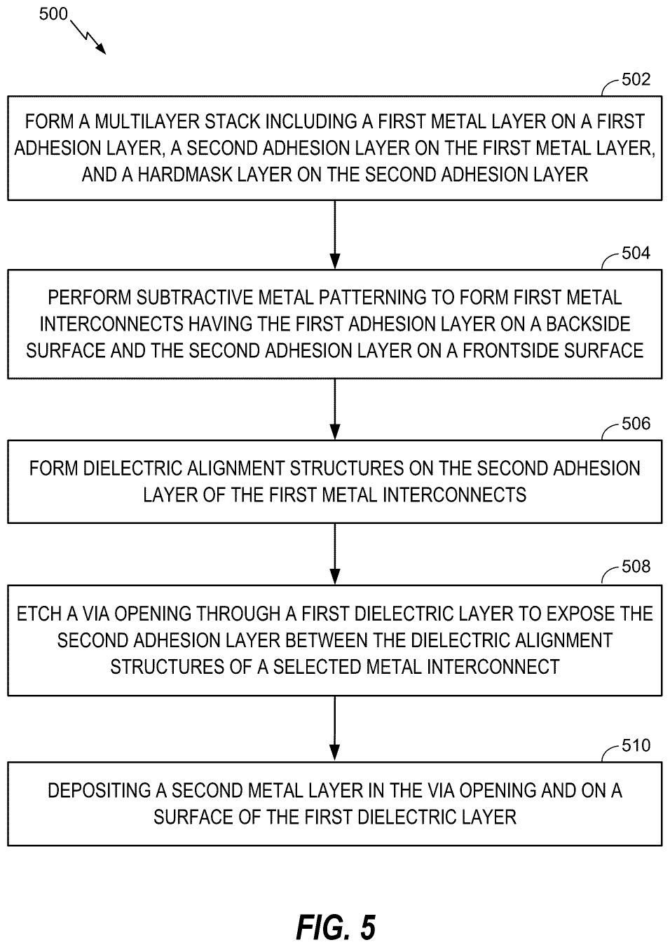

FIG. 5 is a process flow diagram illustrating a method 500 for forming a fully self-aligned via (FSAV) on a subtractive metal, according to aspects of the present disclosure. The method 500 begins at block 502, in which a multilayer stack is formed, including a first metal layer on a first adhesion layer, a second adhesion layer on the first metal layer, and a hardmask layer on the second adhesion layer. For example, as shown in FIG. 4A, an IC device fabrication process begins at step 400, in which a sequential deposition of the first adhesion layer 302 (e.g., TiN), a first alternative metal layer 402 (e.g., Ru, W, and Mo, etc.), and a first hardmask layer 404 (e.g., SiN) forms a multilayer stack. In this example, the first adhesion layer 302 is formed using an ALD of an adhesion material (e.g., TiN) having a predetermined thickness (e.g., ˜0.3 nm). Additionally, the first alternative metal layer 402 is formed of a predetermined thickness (e.g., ˜30 nm) using CVD, PVD, ALD, or other like deposition technique.

At block 504, subtractive metal patterning is performed to form first metal interconnects having the first adhesion layer on a backside surface and the second adhesion layer on a frontside surface. For example, as shown in FIG. 4B, at step 410, subtractive metal patterning on the material stack formed in step 400 of FIG. 4A forms the M0 metal interconnects, including the second adhesion layer 310 and portions 412 of the second hardmask layer 406. In this example, portions of a surface of the first adhesion layer 302 are exposed through the subtractive metal patterning performed at step 410.

At block 506, dielectric alignment structures are formed on the second adhesion layer of the first metal interconnects. For example, as shown in FIG. 4F, at step 450, anisotropic etching of the second dielectric layer 442 exposes a top portion of the second hardmasks 422, and a surface of the first dielectric layer 432 to form the dielectric alignment structures 320 on the second adhesion layer 310. Performing anisotropic etching of the second dielectric layer 442 removes portions of the conformal layer of the second dielectric layer 442 to begin formation of the dielectric alignment structures 320.

At block 508, a via opening is etched through a first dielectric layer to expose the second adhesion layer between the dielectric alignment structures of a selected metal interconnect. For example, as shown in FIG. 4G, at step 460, selective etching of the second hardmasks 422 removes the second hardmasks 422. Removing the second hardmasks 422 exposes a top portion of the second adhesion layer 310 on the M0 metal interconnects through openings 462 between opposing portions of the dielectric alignment structures 320.

At block 510, a second metal layer is deposited in the via opening and on a surface of the first dielectric layer. For example, as shown in FIG. 4J, at step 490, a second alternative metal layer 492 is deposited in the via opening 482 and on an exposed one of the second adhesion layer 310 between dielectric alignment structures 320 of a selected M0 metal interconnect (e.g., a selected metal interconnect). Additionally, the second alternative metal layer 492 is concurrently deposited on a surface of the third dielectric layer 472. In some implementations, the second alternative metal layer 492 (e.g., Ru) fills the via opening 482 (see FIG. 4I) using CVD.

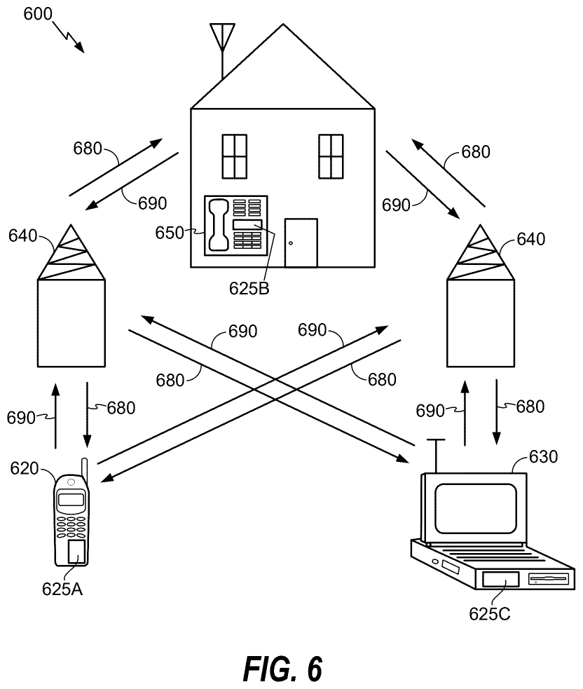

FIG. 6 is a block diagram showing an exemplary wireless communications system 600 in which an aspect of the disclosure may be advantageously employed. For purposes of illustration, FIG. 6 shows three remote units 620, 630, and 650, and two base stations 640. It will be recognized that wireless communications systems may have many more remote units and base stations. Remote units 620, 630, and 650 include integrated circuit (IC) devices 625A, 625C, and 625B that include the disclosed FSAV on a subtractive metal. It will be recognized that other devices may also include the disclosed FSAV on a subtractive metal, such as the base stations 640, switching devices, and network equipment. FIG. 6 shows forward link signals 680 from the base stations 640 to the remote units 620, 630, and 650, and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 6 illustrates remote units according to aspects of the present disclosure, the disclosure is not limited to these exemplary illustrated units. Aspects of the present disclosure may be suitably employed in many devices, which include the disclosed FSAV on a subtractive metal.

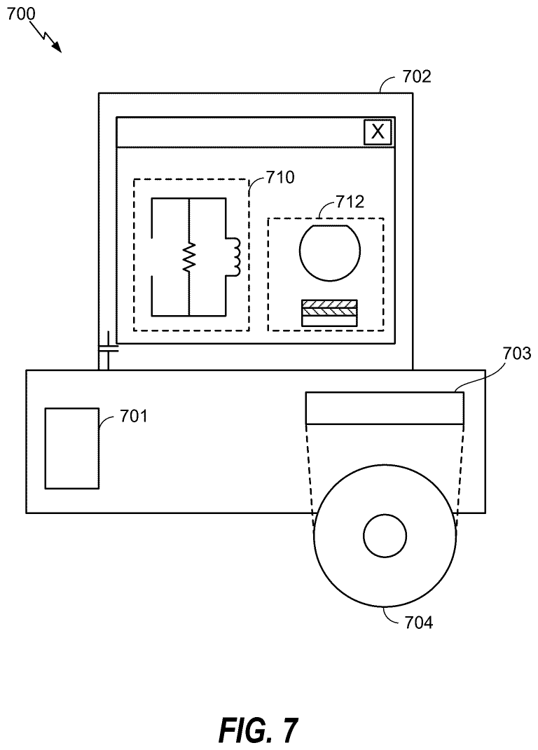

FIG. 7 is a block diagram illustrating a design workstation used for circuit, layout, and logic design of a semiconductor component, such as the FSAV disclosed above. A design workstation 700 includes a hard disk 701 containing operating system software, support files, and design software such as Cadence or OrCAD. The design workstation 700 also includes a display 702 to facilitate design of a circuit 710 or an integrated circuit (IC) component 712 such as an FSAV on a subtractive metal. A storage medium 704 is provided for tangibly storing the design of the circuit 710 or the IC component 712 (e.g., the FSAV on a subtractive metal). The design of the circuit 710 or the IC component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit 710 or the IC component 712 by decreasing the number of processes for designing semiconductor wafers.

Implementation examples are described in the following numbered clauses:
1. An integrated circuit (IC), comprising:
a dielectric layer of a first dielectric material;
a first metal layer in the dielectric layer and having a first adhesion layer on a backside surface, a second adhesion layer on a frontside surface of the first metal layer and dielectric alignment structures on the second adhesion layer of a second dielectric material different from the first dielectric material; and
a second metal layer landing on the second adhesion layer on the frontside surface of the first metal layer, between the dielectric alignment structures.
2. The IC of clause 1, in which the first metal layer comprises a zero-metal layer (M0) interconnect.
3. The IC of any of clauses 1 or 2, in which the second metal layer comprises a fully self-aligned zero metal via (V0) landing on the second adhesion layer on the frontside surface of the first metal layer, between the dielectric alignment structures.
4. The IC of clause 3, in which the second metal layer comprises a first metal layer (M1) interconnect contacted to the V0 via.
5. The IC of any of clauses 1-4, in which the first dielectric material comprises a low-K dielectric material less than four, and the second dielectric material comprises a high-K dielectric material greater than four.
6. The IC of clause 5, in which the low-K dielectric material comprises silicon carbon oxygen hydrogen (SiCOH), silicon oxygen carbon (SiOC), and/or silicon oxide (SiO₂).
7. The IC of clause 5, in which the high-K dielectric material comprises silicon nitride (SiN), aluminum nitride (AlN), and/or aluminum oxide (Al₂O₃).
8. The IC of clause 5, in which the dielectric alignment structures comprises the low-K dielectric material between a pair of the dielectric alignment structures comprising the high-K dielectric material.
9. The IC of any of clauses 1-8, in which the first metal layer comprises ruthenium (Ru), tungsten (W), and/or molybdenum (Mo).
10. The IC of any of clauses 1-9, in which the second metal layer comprises ruthenium (Ru), tungsten (W), and/or molybdenum (Mo).
11. A method for forming a fully self-aligned via, comprising:
forming a multilayer stack including a first metal layer on a first adhesion layer, a second adhesion layer on the first metal layer, and a hardmask layer on the second adhesion layer;
performing subtractive metal patterning to form first metal interconnects having the first adhesion layer on a backside surface and the second adhesion layer on a frontside surface;
forming dielectric alignment structures on the second adhesion layer of the first metal interconnects;
etching a via opening through a first dielectric layer to expose the second adhesion layer between the dielectric alignment structures of a selected metal interconnect; and
depositing a second metal layer in the via opening and on a surface of the first dielectric layer.
12. The method of clause 11, in which forming the dielectric alignment structures comprises:
depositing the first dielectric layer on the first adhesion layer, sidewalls of the first metal interconnects, and sidewalls of the second adhesion layer on the first metal interconnects;
conformally depositing a second dielectric layer on the hardmask layer, an exposed portion of the second adhesion layer, and a surface of the first dielectric layer;
performing anisotropic etching of the second dielectric layer to expose a top portion of the hardmask layer, and the surface of the first dielectric layer to form the dielectric alignment structures on the second adhesion layer; and
selectively etching the portions of the hardmask layer from the exposed top portion to expose the second adhesion layer on the first metal interconnects through the dielectric alignment structures.
13. The method of clause 12, further comprising depositing a third dielectric layer on the surface of the first dielectric layer, the dielectric alignment structures, and the exposed portion of the second adhesion layer on the first metal interconnects.
14. The method of any of clauses 11-13, in which depositing the second metal layer comprises forming the self-aligned via landing on the second adhesion layer exposed between the dielectric alignment structures of the selected metal interconnect.
15. The method of any of clauses 11-14, in which depositing the second metal layer comprises performing a subtractive metal etch of the second metal layer to form a second metal layer interconnect.
16. The method of clause 15, further comprising:
depositing a third dielectric layer to fill an area previously occupied by the second metal layer; and
performing a chemical mechanical polishing (CMP) planarization of the third dielectric layer.
17. The method of any of clauses 11-16, in which the first dielectric layer comprises a low-K dielectric material less than four, and the dielectric alignment structures comprise a high-K dielectric material greater than four.
18. The method of clause 17, in which the low-K dielectric material comprises silicon carbon oxygen hydrogen (SiCOH), silicon oxygen carbon (SiOC), and/or silicon oxide (SiO₂).
19. The method of clause 17, in which the high-K dielectric material comprises silicon nitride (SiN), aluminum nitride (AlN), and/or aluminum oxide (Al₂O₃).
20. The method of any of clauses 11-19, in which the first metal layer comprises ruthenium (Ru), tungsten (W), and/or molybdenum (Mo) and the second metal layer comprises the ruthenium (Ru).

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC), comprising:
a dielectric layer of a first dielectric material;
a first metal layer in the dielectric layer and having a first adhesion layer on a backside surface, a second adhesion layer on a frontside surface of the first metal layer and dielectric alignment structures on the second adhesion layer of a second dielectric material different from the first dielectric material; and
a second metal layer landing on the second adhesion layer on the frontside surface of the first metal layer, between the dielectric alignment structures.

2. The IC of claim 1, in which the first metal layer comprises a zero-metal layer (M0) interconnect.

3. The IC of claim 1, in which the second metal layer comprises a fully self-aligned zero metal via (V0) landing on the second adhesion layer on the frontside surface of the first metal layer, between the dielectric alignment structures.

4. The IC of claim 3, in which the second metal layer comprises a first metal layer (M1) interconnect contacted to the V0 via.

5. The IC of claim 1, in which the first dielectric material comprises a low-K dielectric material less than four, and the second dielectric material comprises a high-K dielectric material greater than four.

6. The IC of claim 5, in which the low-K dielectric material comprises silicon carbon oxygen hydrogen (SiCOH), silicon oxygen carbon (SiOC), and/or silicon oxide (SiO₂).

7. The IC of claim 5, in which the high-K dielectric material comprises silicon nitride (SiN), aluminum nitride (AlN), and/or aluminum oxide (Al₂O₃).

8. The IC of claim 5, in which the dielectric alignment structures comprises the low-K dielectric material between a pair of the dielectric alignment structures comprising the high-K dielectric material.

9. The IC of claim 1, in which the first metal layer comprises ruthenium (Ru), tungsten (W), and/or molybdenum (Mo).

10. The IC of claim 1, in which the second metal layer comprises ruthenium (Ru), tungsten (W), and/or molybdenum (Mo).

11. A method for forming a fully self-aligned via, comprising:
forming a multilayer stack including a first metal layer on a first adhesion layer, a second adhesion layer on the first metal layer, and a hardmask layer on the second adhesion layer;
performing subtractive metal patterning to form first metal interconnects having the first adhesion layer on a backside surface and the second adhesion layer on a frontside surface;
forming dielectric alignment structures on the second adhesion layer of the first metal interconnects;
etching a via opening through a first dielectric layer to expose the second adhesion layer between the dielectric alignment structures of a selected metal interconnect; and
depositing a second metal layer in the via opening and on a surface of the first dielectric layer.

12. The method of claim 11, in which forming the dielectric alignment structures comprises:
depositing the first dielectric layer on the first adhesion layer, sidewalls of the first metal interconnects, and sidewalls of the second adhesion layer on the first metal interconnects;
conformally depositing a second dielectric layer on the hardmask layer, an exposed portion of the second adhesion layer, and a surface of the first dielectric layer;
performing anisotropic etching of the second dielectric layer to expose a top portion of the hardmask layer, and the surface of the first dielectric layer to form the dielectric alignment structures on the second adhesion layer; and
selectively etching the portions of the hardmask layer from the exposed top portion to expose the second adhesion layer on the first metal interconnects through the dielectric alignment structures.

13. The method of claim 12, further comprising depositing a third dielectric layer on the surface of the first dielectric layer, the dielectric alignment structures, and the exposed portion of the second adhesion layer on the first metal interconnects.

14. The method of claim 11, in which depositing the second metal layer comprises forming the self-aligned via landing on the second adhesion layer exposed between the dielectric alignment structures of the selected metal interconnect.

15. The method of claim 11, in which depositing the second metal layer comprises performing a subtractive metal etch of the second metal layer to form a second metal layer interconnect.

16. The method of claim 15, further comprising:
depositing a third dielectric layer to fill an area previously occupied by the second metal layer; and
performing a chemical mechanical polishing (CMP) planarization of the third dielectric layer.

17. The method of claim 11, in which the first dielectric layer comprises a low-K dielectric material less than four, and the dielectric alignment structures comprise a high-K dielectric material greater than four.

18. The method of claim 17, in which the low-K dielectric material comprises silicon carbon oxygen hydrogen (SiCOH), silicon oxygen carbon (SiOC), and/or silicon oxide (SiO₂).

19. The method of claim 17, in which the high-K dielectric material comprises silicon nitride (SiN), aluminum nitride (AlN), and/or aluminum oxide (Al₂O₃).

20. The method of claim 11, in which the first metal layer comprises ruthenium (Ru), tungsten (W), and/or molybdenum (Mo) and the second metal layer comprises the ruthenium (Ru).
